(19) United States
(12) Patent Application Publication
(10) Pub. No.: US 2020/0135615 A1
(43) Pub. Date: Apr. 30, 2020

(54) CHIP PACKAGE STRUCTURE

(71) Applicant: HUAWEI TECHNOLOGIES CO., LTD., Shenzhen (CN)

(72) Inventors: HuiLi FU, Shenzhen (CN); Jyh Rong LIN, Taiwan (CN); Xiangxiong ZHANG, Shenzhen (CN); Shujie CAI, Shenzhen (CN)

(21) Appl. No.: 16/723,269

(22) Filed: Dec. 20, 2019

Related U.S. Application Data
(63) Continuation of application No. PCT/CN2018/092246, filed on Jun. 21, 2018.

(30) Foreign Application Priority Data
Jun. 21, 2017 (CN) 201710479072.2

(51) Int. Cl. H01L 23/427; H01L 23/38; H01L 25/18; H01L 23/00

(52) U.S. Cl. CPC H01L 23/427; H01L 23/38; H01L 25/18; H01L 2224/32221; H01L 24/32; H01L 2224/73253; H01L 24/73

(57) ABSTRACT

This application provides a chip package structure. The chip package structure includes: a substrate and a chip, and further includes: a heat dissipation ring fastened onto the substrate and a planar heat pipe radiator covering the heat dissipation ring. The substrate, the heat dissipation ring, and the planar heat pipe radiator form a space to enclose the chip. A first metal thin film is disposed on a surface, facing the chip, of the planar heat pipe radiator, and the chip is thermally coupled to the first metal thin film by using a sintered metal layer.

### CROSS-REFERENCE TO RELATED APPLICATIONS

This application is a continuation of International Application No. PCT/CN2018/092246, filed on Jun. 21, 2018, which claims priority to Chinese Patent Application No. 201710479072.2, filed on Jun. 21, 2017. The disclosures of the aforementioned applications are hereby incorporated by reference in their entireties.

### TECHNICAL FIELD

This application relates to the field of information technologies, and in particular, to a chip package structure.

### BACKGROUND

As a quantity of chip process nodes keeps decreasing and a chip integration level keeps increasing, a plurality of heterogeneous chips (for example, a logic chip and a memory) and passive components are packaged and integrated into a small-sized system in a system-level chip package. Both overall power consumption of the package and single-chip power consumption continuously increase. Temperatures of the chips need to be kept within a given range to ensure long-term and stable operation of the chips. This is a major challenge now confronted in the system-level chip package.

Currently, a key idea of transferring chip heat faster to outside of package is to reduce thermal resistance of a heat transfer path by introducing materials with higher thermal conductivity or by optimizing a package structure. FIG. 1 shows a heat dissipation mode in the prior art. A chip 2 is fastened onto a substrate 1 by using solder balls 4, and connected to a planar heat pipe 5 with super-high thermal conductivity by using a thermal interface material layer 3. A conventional heat dissipation cover (copper) is replaced by the planar heat pipe 5 to improve heat transfer from the chip 2 to a package surface 6.

However, thermal resistance of the conventional thermal interface material layer 3 is quite high. This severely limits benefits of using the planar heat pipe, and becomes a main bottleneck for a heat dissipation path of the chip. In addition, only a passive heat dissipation solution is used for a conventional package structure, and this limits control of a chip temperature to some extent.

### SUMMARY

This application provides a chip package structure, to solve a heat dissipation problem of a prior-art chip package structure.

According to a first aspect, a chip package structure is provided. The chip package structure includes: a substrate and a chip, and further includes: a heat dissipation ring fastened onto the substrate and a planar heat pipe radiator covering the heat dissipation ring. The substrate, the heat dissipation ring, and the planar heat pipe radiator form a space to enclose the chip. The chip is located within the space and fastened onto the substrate, a first metal thin film is disposed on a surface, facing the chip, of the planar heat pipe radiator, and the chip is thermally coupled to the first metal thin film by using a sintered metal layer.

In one embodiment, the planar heat pipe radiator is used to dissipate heat of the chip. In addition, to improve a capability of heat dissipation from the chip to the planar heat pipe radiator, the first metal thin film is disposed on the surface of the planar heat pipe radiator, and the first metal thin film is thermally coupled to the chip by using the sintered metal layer. The sintered metal layer has a good heat transfer effect and can quickly transfer heat to the planar heat pipe radiator, thereby effectively improving a heat dissipation effect of the chip.

In one embodiment, a second metal thin film is disposed on a surface, facing the planar heat pipe radiator, of the chip, and the sintered metal layer is thermally coupled to the second metal thin film. Disposing the second metal thin film on the chip further improves the heat dissipation effect of the chip.

In one embodiment, the sintered metal layer includes a plurality of metal particles and a filling layer enclosing the plurality of metal particles. The metal particles may be silver particles, aluminum particles, copper particles, magnesium particles, or gold particles.

In one embodiment, the metal particles are sintered with the first metal thin film and the second metal thin film to form an atomic continuous phase structure, to further improve the heat dissipation effect.

In one embodiment, the filling layer is an air layer or an adhesive layer. The filling layer is formed by using different materials.

In one embodiment, the first metal thin film is disposed on the planar heat pipe radiator in a sputtering or electroplating manner, and the second metal thin film is disposed on the chip in a sputtering or electroplating manner. The first metal thin film and the second metal thin film are formed by using different processes.

In one embodiment, there are m chips, a thermoelectric cooler is disposed between n chips and the planar heat pipe radiator, one surface of the thermoelectric cooler is connected to the planar heat pipe radiator, and the other surface of the thermoelectric cooler is thermally coupled to the chips by using the sintered metal layer. Both m and n are integers, m≥1, and m≥n. The thermoelectric cooler further improves the heat dissipation effect.

In one embodiment, the thermoelectric cooler is a power-adjustable thermoelectric cooler. Therefore, power of the thermoelectric cooler can be adjusted according to different heat dissipation requirements.

In one embodiment, a third metal thin film is disposed on a surface, facing the chip, of the thermoelectric cooler, to further improve the heat dissipation effect.

In one embodiment, the third metal thin film is disposed on the thermoelectric cooler in a sputtering or electroplating manner. The third metal thin film is formed by using different processes.

In one embodiment, the heat dissipation ring is separately bonded to the substrate and the planar heat pipe radiator. The heat dissipation ring and the planar heat pipe radiator use a separated structure.

In one embodiment, the heat dissipation ring is integrated with the planar heat pipe radiator, and the heat dissipation ring is bonded to the substrate. The heat dissipation ring and the planar heat pipe radiator use an integrated structure.

### BRIEF DESCRIPTION OF DRAWINGS

FIG. 1 is a schematic structural diagram of a prior-art chip package structure;

FIG. 2 is a schematic structural diagram of a chip package structure according to this application;

FIG. 3 is a schematic structural diagram of another chip package structure according to this application;

FIG. 4 is a schematic structural diagram of a chip and a planar heat pipe radiator according to this application;

FIG. 5 is a schematic structural diagram of still another chip package structure according to this application; and

FIG. 6 is a schematic structural diagram of yet another chip package structure according to this application.

### DESCRIPTION OF EMBODIMENTS

To make the objectives, technical solutions, and advantages of this application clearer, the following further describes this application in detail with reference to the accompanying drawings.

This application provides a chip package structure. The chip package structure includes a substrate and a chip. The chip includes, but is not limited to, a wire bonding chip and a flip chip.

There may be one or more chips. When a plurality of chips are used, types of the chips may be different. In an embodiment shown in FIG. 2, a substrate 101 may be bonded to another substrate or device by using solder balls 100. There are two chips, and the two chips are a logic chip 104 and a memory chip 105. The chips may alternatively be other types of chips. The logic chip 104 and the memory chip 105 are merely used as examples. During chip disposition, the chips are fastened onto the substrate 101, and a heat dissipation ring 103 is also fastened onto the substrate 101. The heat dissipation ring 103 is a frame structure, and the heat dissipation ring 103 is also covered with a planar heat pipe radiator 107, so that the substrate 101, the heat dissipation ring 103, and the planar heat pipe radiator 107 form a space to enclose the chips. As shown in FIG. 2, the logic chip 104 and the memory chip 105 are fastened onto the substrate 101. During specific connection, the chips can be fastened onto the substrate 101 by using solder balls 109. As shown in FIG. 2, the logic chip 104 and the memory chip 105 are soldered to the substrate 101 by using the solder balls 109. In this way, the logic chip 104 and the memory chip 105 can be reliably fastened onto the substrate 101.

To improve a heat dissipation effect of the chips, the chip package structure provided in this embodiment uses different manners to dissipate heat of the chips. The following uses specific embodiments for description.

### Embodiment 1

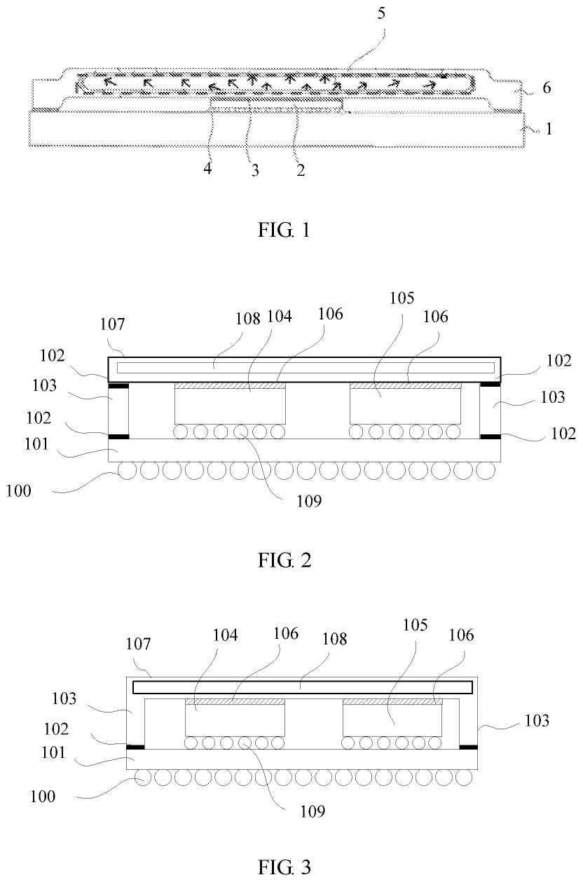

Further referring to FIG. 2 and FIG. 3, as shown in FIG. 1, a chip package structure includes one substrate 101 and two chips, namely, a logic chip 104 and a memory chip 105. The chips are fastened onto the substrate 101, and a heat dissipation ring 103 is also fastened onto the substrate 101. The heat dissipation ring 103 is a frame structure, and the heat dissipation ring 103 is also covered with a planar heat pipe radiator 107, so that the substrate 101, the heat dissipation ring 103, and the planar heat pipe radiator 107 form a space to enclose the chips. As shown in FIG. 2, the logic chip 104 and the memory chip 105 are fastened onto the substrate 101. During specific connection, the chips can be fastened onto the substrate 101 by using solder balls 109. As shown in FIG. 2, the logic chip 104 and the memory chip 105 are soldered to the substrate 101 by using the solder balls 109. In this way, the logic chip 104 and the memory chip 105 can be reliably fastened onto the substrate 101.

During specific connection, according to one embodiment, the heat dissipation ring 103 and the planar heat pipe radiator 107 may be connected in different manners. The heat dissipation ring 103 and the planar heat pipe radiator 107 may be disposed in a separated or an integrated manner. As shown in FIG. 2, in the structure shown in FIG. 2, the heat dissipation ring 103 and the planar heat pipe radiator 107 use a separated design manner. In this case, the heat dissipation ring 103 is separately bonded to the substrate 101 and the planar heat pipe radiator 107. To be specific, one side of the heat dissipation ring 103 is bonded to the substrate 101 by using adhesive 102, and the other side is bonded to the planar heat pipe radiator 107 by using the adhesive 102. As shown in FIG. 3, in the structure shown in FIG. 3, the heat dissipation ring 103 and the planar heat pipe radiator 107 use an integrated structure. In this case, the heat dissipation ring 103 and the planar heat pipe radiator 107 are integrated into a housing structure by using a mold. After the chips are fastened onto the substrate 101, this housing is covered on the substrate 101 to enclose the chips. When this structure is used, the heat dissipation ring 103 and the substrate 101 are connected through bonding. For example, the heat dissipation ring 103 is bonded to the substrate 101 by using the adhesive 102.

In one embodiment, the heat dissipation ring 103 and the planar heat pipe radiator 107 are used for heat dissipation of the chip package structure. As shown in FIG. 2, this planar heat pipe radiator 107 serves as a heat dissipation cover. The planar heat pipe radiator 107 can enhance heat evenness on the heat dissipation cover, to accelerate heat transfer from the heat dissipation cover to an external environment (including external radiators), thereby effectively reducing a junction temperature of the chips. During specific preparation, a hollow cavity 108 is formed within the heat dissipation cover. When the heat dissipation ring 103 is connected to the planar heat pipe radiator 107, the heat dissipation ring 103 is bonded to the heat dissipation cover. When the planar heat pipe radiator 107 and the heat dissipation ring 103 form an integrated structure, the heat dissipation ring 103 and the heat dissipation cover form an integrated structure.

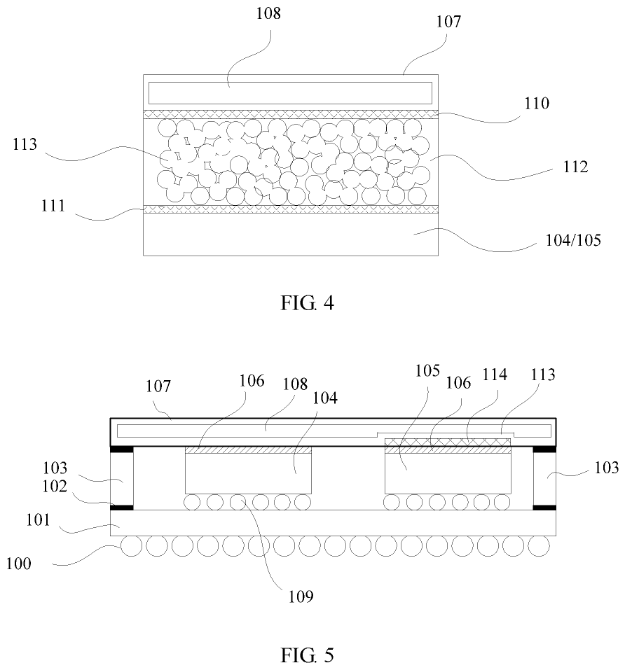

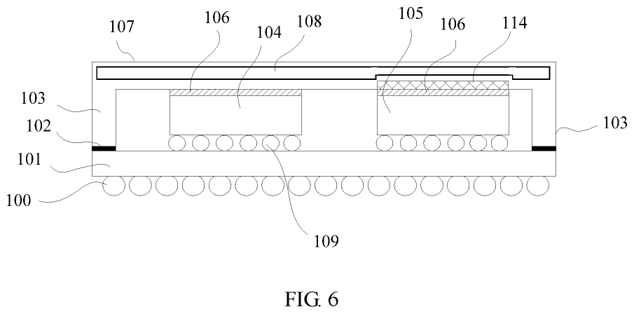

When the chips are connected to the planar heat pipe radiator 107, according to one embodiment, to improve a heat dissipation effect, a first metal thin film 110 is disposed on a surface, facing the chip, of the planar heat pipe radiator 107 provided in this embodiment. The first metal thin film 110 is a metal thin film formed on the chips in a sputtering or electroplating manner. It should be understood that a manner of forming the first metal thin film 110 includes, but is not limited to, the sputtering and electroplating manners, and may alternatively be another preparation manner. The chips are thermally coupled to the first metal thin film 110 by using a sintered metal layer 106. Specifically, as shown in FIG. 2, a surface, facing the planar heat pipe radiator 107, of the logic chip 104 or the memory chip 105 is connected to the first metal thin film 110 by using the sintered metal layer 106. As shown in FIG. 4, the sintered metal layer 106 includes a plurality of metal particles 113 and a filling layer 112 enclosing the plurality of metal particles 113. The filling layer 112 is an air layer or an adhesive layer, or the filling layer 112 formed by using another material. In addition, an atomic continuous phase structure is formed between the first metal thin film 110 and the metal particles 113, to reduce thermal resistance of a connection structure between the chips and the planar heat pipe radiator 107 and improve the heat dissipation effect. The metal particles 113 may be metal particles, such as silver particles, aluminum particles, copper particles, magnesium particles, or gold particles.

To further improve the heat dissipation effect, according to another embodiment, a second metal thin film 111 is provided on the surfaces, facing the planar heat pipe radiator 107, of the chips, and the sintered metal layer 106 and the second metal thin film 111 are thermally coupled, to further reduce the thermal resistance of the connection structure between the chips and the planar heat pipe radiator 107 and improve the heat dissipation effect. During specific disposition, the second metal thin film 111 is formed on the chips in an electroplating or sputtering manner. It should be understood that a manner of forming the second metal thin film 111 includes, but is not limited to, the sputtering and electroplating manners, and may alternatively be another preparation manner. In the structure shown in FIG. 2, one or more second metal thin films 111 are formed in the electroplating or sputtering manner on a surface, facing the planar heat pipe radiator 107, of the memory chip 105 and the logic chip 104. When the second metal thin film 111 is connected to the sintered metal layer 106, the second metal thin film 111 and the metal particles 113 in the sintered metal layer 106 form an atomic continuous phase structure. In this case, heat dissipation channels formed between the chips and the planar heat pipe radiator 107 include: the first metal thin film 110, the sintered metal layer 106, and the second metal thin film 111. During disposition, the sintered metal layer 106, the first metal thin film 110, and the second metal thin film 111 are sintered to form the atomic continuous phase structure. This can effectively reduce thermal resistance of the first metal thin film 110, the sintered metal layer 106, and the second metal thin film 111, and heat on the chips can be quickly transferred to the planar heat pipe radiator 107.

It can be learned, from the foregoing descriptions, that this application provides a chip package structure that can improve the heat dissipation effect. The chip package structure can improve a heat dissipation capability of the package structure when a plurality of chips are packaged at a system level, and can effectively control a chip temperature. The chip package structure provided in this application can rapidly transfer heat generated by different chips to the planar heat pipe radiator 107 through the sintered metal layer 106. Compared with a thermal interface material layer that is used in a prior-art chip package structure and that has a thermal conductivity of a thermal interface material being a magnitude of 4 W/mK, a thermal conductivity of the sintered metal layer 106 in this embodiment reaches a magnitude of 100 W/mK. Therefore, using the sintered metal layer 106 can reduce thermal resistance between the chips and the planar heat pipe radiator 107 by about 25 times, and effectively reduce the junction temperature of the chips, the heat can be transferred to the planar heat pipe radiator 107 as soon as possible, and the planar heat pipe radiator 107 can quickly homogenize the heat. This strengthens a capability of transferring the heat from the planar heat pipe radiator 107 to the environment, and effectively reduces the junction temperature of the chips, especially high-power chips.

### Embodiment 2

As shown in FIG. 4 and FIG. 5, a substrate 101, chips, a planar heat pipe radiator 107, and a heat dissipation ring 103 in a chip package structure provided in this embodiment may all use the structure in the foregoing embodiment 1.

As shown in FIG. 4, the heat dissipation ring 103 and the planar heat pipe radiator 107 use a separated design manner. In one embodiment, the heat dissipation ring 103 is separately bonded to the substrate 101 and the planar heat pipe radiator 107. To be specific, one side of the heat dissipation ring 103 is bonded to the substrate 101 by using adhesive 102, and the other side is bonded to the planar heat pipe radiator 107 by using the adhesive 102. As shown in FIG. 5, in the structure shown in FIG. 5, the heat dissipation ring 103 and the planar heat pipe radiator 107 use an integrated structure. In this case, the heat dissipation ring 103 and the planar heat pipe radiator 107 are integrated into a housing structure by using a mold. After the chips are fastened onto the substrate 101, this housing is covered on the substrate 101 to enclose the chips. When this structure is used, the heat dissipation ring 103 and the substrate 101 are connected through bonding. As shown in FIG. 5, the heat dissipation ring 103 is bonded to the substrate 101 by using the adhesive 102.

In the chip package structure provided in this embodiment of this application, in order to further improve a heat dissipation effect of the chip package structure, a thermoelectric cooler 114 is added. When there are a plurality of chips, corresponding thermoelectric coolers 114 are disposed for chips that generate more heat at work, or corresponding thermoelectric coolers 114 may be disposed for all chips. For example, there are m chips, the thermoelectric cooler 114 is disposed between n chips and the planar heat pipe radiator 107, one surface of the thermoelectric cooler 114 is connected to the planar heat pipe radiator 107, and the other surface of the thermoelectric cooler is thermally coupled to the chips by using a sintered metal layer 106. Both m and n are integers, m≥1, and m≥n. In structures shown in FIG. 3 and FIG. 4, there are two chips, namely a logic chip 104 and a memory chip 105. The memory chip 105 corresponds to one thermoelectric cooler 114. In this case, m=2 and n=1. During specific disposition, the thermoelectric cooler 114 is bonded to the planar heat pipe radiator 107, and a third metal thin film is disposed on a surface, facing the chip, of the thermoelectric cooler 114. In the structure shown in FIG. 3, one or more third metal thin films are formed on the memory chip 105 in a sputtering or electroplating manner. It should be understood that a manner of forming the third metal thin film includes, but is not limited to, the sputtering and electroplating manners, and may alternatively be another preparation manner. In this case, heat dissipation channels formed between the memory chip 105 and the planar heat pipe radiator 107 include: a second metal thin film 111, the sintered metal layer 106, the third metal thin film, and the thermoelectric cooler 114. During specific disposition, an atomic continuous phase structure is used between the second metal thin film 111 and metal particles 113 in the sintered metal layer 106, and between the third metal thin film and the metal particles 113 in the sintered metal layer 106. This can effectively reduce thermal resistance of the heat dissipation channels. In addition, the thermoelectric cooler 114 can be disposed to effectively control a chip temperature. During specific disposition, the thermoelectric cooler 114 is a power-adjustable thermoelectric cooler 114. Therefore, power of the thermoelectric cooler 114 can be adjusted according to different heat dissipation requirements.

In the structures shown in FIG. 4 and FIG. 5, only two-chip structures are shown. It should be understood that when a plurality of chips are used, different quantities of the thermoelectric coolers 114 may be disposed according to an actual requirement.

It can be learned, from the foregoing description, that when the chip temperature needs to be controlled, the thermoelectric coolers 114 are disposed to adjust the chip temperature, further improve the heat dissipation effect, and ensure stable operation of the chips.

The foregoing embodiment 1 and embodiment 2 merely show heat dissipation structures for specific chip package structures. For the chip package structures in the embodiments of this application, the heat dissipation structures shown in embodiment 1 and embodiment 2 can be used regardless of a quantity of chips. The atomic continuous phase structure formed between the sintered metal layer 106 and the metal thin films can effectively reduce the thermal resistance between the chips and the planer heat pipe radiator 107, thereby effectively improving the heat dissipation effect of the chip package structure.

Obviously, a person skilled in the art can make various modifications and variations to this application without departing from the spirit and scope of this application. This application is intended to cover these modifications and variations of this application provided that they fall within the scope of protection defined by the following claims and their equivalent technologies.

What is claimed is:

1. A chip package structure, comprising:
a substrate; and
a chip;
a heat dissipation ring fastened onto the substrate and a planar heat pipe radiator covering the heat dissipation ring, wherein the substrate, the heat dissipation ring, and the planar heat pipe radiator form a space to enclose the chip, wherein the chip is located within the space and fastened onto the substrate, a first metal thin film is disposed on a surface of the planar heat pipe radiator, facing the chip, and the chip is thermally coupled to the first metal thin film by using a sintered metal layer.

2. The chip package structure according to claim 1, wherein a second metal thin film is disposed on a surface of the chip, facing the planar heat pipe radiator, and the sintered metal layer is thermally coupled to the second metal thin film.

3. The chip package structure according to claim 2, wherein the sintered metal layer comprises a plurality of metal particles and a filling layer enclosing the plurality of metal particles.

4. The chip package structure according to claim 3, wherein the metal particles are silver particles, aluminum particles, copper particles, magnesium particles, or gold particles.

5. The chip package structure according to claim 3, wherein the metal particles are sintered with the first metal thin film and the second metal thin film to form an atomic continuous phase structure.

6. The chip package structure according to claim 3, wherein the filling layer is an air layer or an adhesive layer.

7. The chip package structure according to claim 2, wherein the first metal thin film is disposed on the planar heat pipe radiator in a sputtering or electroplating manner, and the second metal thin film is disposed on the chip in a sputtering or electroplating manner.

8. The chip package structure according to claim 1, wherein there are m chips, a thermoelectric cooler is disposed between n chips and the planar heat pipe radiator, one surface of the thermoelectric cooler is connected to the planar heat pipe radiator, and the other surface of the thermoelectric cooler is thermally coupled to the chips by using the sintered metal layer, wherein both m and n are integers, m≥1, and m≥n.

9. The chip package structure according to claim 8, wherein the thermoelectric cooler is a power-adjustable thermoelectric cooler.

10. The chip package structure according to claim 8, wherein a third metal thin film is disposed on a surface, facing the chip, of the thermoelectric cooler.

11. The chip package structure according to claim 9, wherein the third metal thin film is disposed on the thermoelectric cooler in a sputtering or electroplating manner.

12. The chip package structure according to claim 1, wherein the heat dissipation ring is separately bonded to the substrate and the planar heat pipe radiator.

13. The chip package structure according to claim 1, wherein the heat dissipation ring is integrated with the planar heat pipe radiator, and the heat dissipation ring is bonded to the substrate.
